(19) United States
(12) Patent Application Publication
(10) Pub. No.: US 2013/0064973 A1
(43) Pub. Date: Mar. 14, 2013

(54) Chamber Conditioning Method

(71) Applicants: Yen-Yu Chen, Taichung City (TW); Chia-Ming Tsai, Zhubei City (TW); Liang-Chen Chi, Hsin-Chu (TW); Jian-Yuan Chen, Zhubei City (TW); Ke-Chih Liu, Hsin-Chu (TW)

(72) Inventors: Yen-Yu Chen, Taichung City (TW); Chia-Ming Tsai, Zhubei City (TW); Liang-Chen Chi, Hsin-Chu (TW); Jian-Yuan Chen, Zhubei City (TW); Ke-Chih Liu, Hsin-Chu (TW)

(73) Assignee: Taiwan Semiconductor Manufacturing Company, Ltd., Hsin-Chu (TW)

(21) Appl. No.: 13/228,995

(22) Filed: Sep. 9, 2011

(51) Int. Cl. B05D 5/00; C23C 16/40; C23C 16/44; B05D 1/36

(52) U.S. Cl. 427/248.1; 427/258; 427/402

(57) ABSTRACT

A system and method for conditioning a chamber is disclosed. An embodiment comprises utilizing the deposition chamber to deposit a first layer and conditioning the deposition chamber. The conditioning the deposition chamber can be performed by depositing a heterogeneous material over the first layer. The heterogeneous material can cover and encapsulate the first layer, thereby preventing particles of the first layer from breaking off and potentially landing on a substrate during a subsequent processing run.

### BACKGROUND

Generally, a deposition process such as atomic layer deposition utilizes a series of sequentially introduced precursor materials in a series of self-limiting reactions to form an atomic monolayer of material onto a semiconductor substrate. For example, a first precursor material in a gaseous state may be introduced and adsorbed onto a surface of a semiconductor substrate, stopping when each of the active sites on the substrate surface is bonded to a molecule of the first precursor material, thereby limiting the depth of the first precursor material to an atomic monolayer. After the atomic monolayer has been formed, the gaseous first precursor material may be removed from the chamber and a second precursor material may be introduced to react with the first precursor material to form a monolayer of the desired layer of material in another self-limiting reaction.

However, during this process of deposition onto a semiconductor substrate, precursor materials will adsorb onto not only the semiconductor substrate but also onto any other surface exposed to the precursor materials. In particular, the precursor materials will adsorb onto the surface of the deposition chamber itself, such as the sidewalls, top, and bottom surfaces of the deposition chamber. As such, a layer of the material that is being deposited on the semiconductor substrate will also be formed on the surfaces of the deposition chamber.

However, there are some materials that can have a deleterious effect on the life span of the deposition chamber. Materials such as high-k dielectrics like hafnium oxide, zirconium oxide, and other ceramics can a small ductility and can also have a poor adhesion to the surfaces of the deposition chamber. As such, after these materials have been formed in one process, particles of the formed material may break off in a subsequent process and land on subsequent substrates, causing defects in subsequently formed semiconductor devices. Once the particles reach a certain size, preventative maintenance may be needed to replace valves, shields, and gas lines of the deposition chamber in order to prepare the deposition chamber for further use.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 illustrates a deposition chamber with precursor delivery systems in accordance with an embodiment;

FIG. 2 illustrates a control unit that may be used with the deposition chamber in accordance with an embodiment;

FIG. 3 illustrates an enlarged view of a surface of the deposition chamber after it has deposited a first layer in accordance with an embodiment;

FIG. 4 illustrates an enlarged view of the surface of the deposition chamber after it has been conditioned in accordance with an embodiment;

FIG. 5 illustrates an enlarged view of the surface of the deposition chamber after repeated usage and conditioning in accordance with an embodiment;

FIG. 6 illustrates a count of particles that are greater than 1 μm when different embodiments are utilized in accordance with an embodiment;

FIG. 7 illustrates an enlarged view of the surface of the deposition chamber that has been preconditioned in accordance with an embodiment; and

FIG. 8 illustrates an enlarged view of the surface of the deposition chamber with multiple bi-layers on it in accordance with an embodiment.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments are discussed in detail below. It should be appreciated, however, that the embodiments provide many applicable concepts that can be embodied in a wide variety of specific contexts. The specific embodiments discussed are merely illustrative of specific ways to make and use the embodiments, and do not limit the scope of the embodiments.

The embodiments will be described with respect to an embodiment in a specific context, namely an atomic layer deposition chamber conditioning process. The embodiments may also be applied, however, to other conditioning processes.

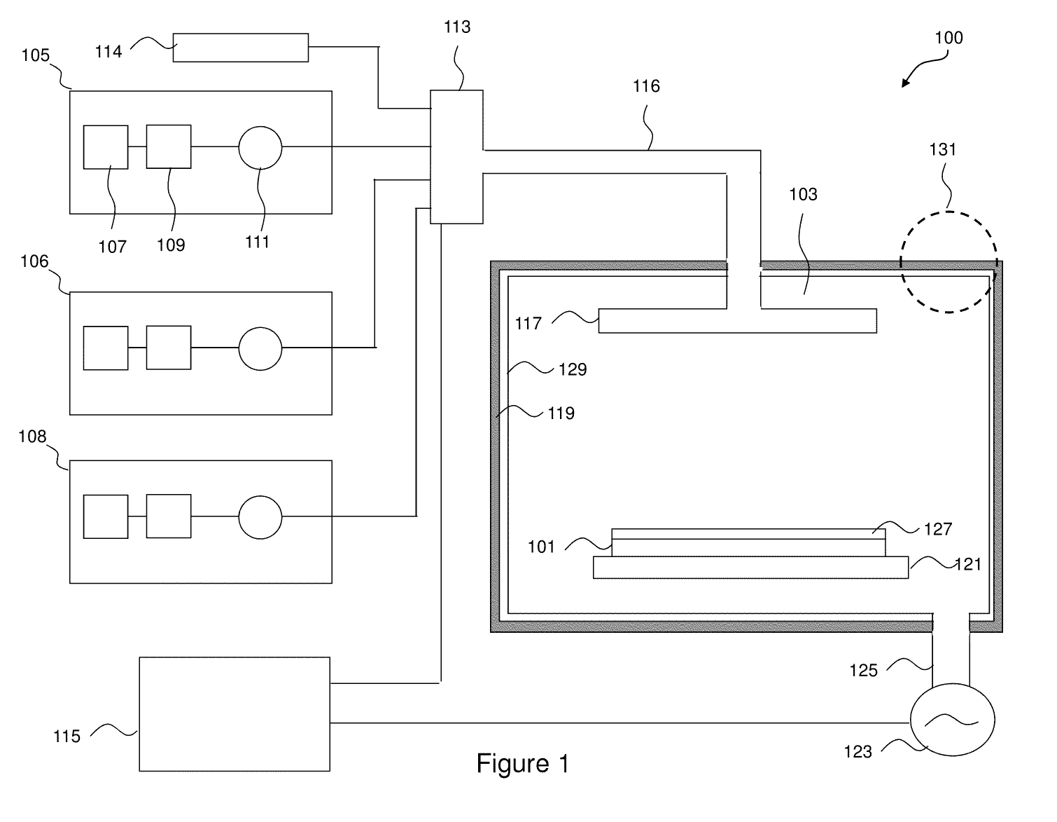

With reference now to FIG. 1, there is shown a deposition system 100 that may be utilized to receive precursor materials from a first precursor delivery system 105, a second precursor delivery system 106, and a third precursor delivery system 108, and to form layers of materials onto a substrate 101 in a deposition chamber 103. The substrate 101 may be, e.g., any substrate upon which a thin film is desired to be formed. In an embodiment the substrate 101 may be a semiconductor substrate such as a process wafer with an exposed surface onto which a layer is desired to be formed. The exposed surface may be a surface of semiconductor material (such as a base silicon wafer), a surface of dielectric material (such as a patterned wafer with a silicon substrate), a surface of a metallization layer, or any other suitable surface for the deposition of the desired layer.

The first precursor delivery system 105, the second precursor delivery system 106, and the third precursor delivery system 108 may work in conjunction with one another to supply the various different precursor materials to the deposition chamber 103. However, the first precursor delivery system 105, the second precursor delivery system 106, and the third precursor delivery system 108 may have physical components that are similar with each other. For example, the first precursor delivery system 105, the second precursor delivery system 106, and the third precursor delivery system 108 may each include a carrier gas supply 107, a flow controller 109, and a precursor canister 111 (labeled in FIG. 1 with regards to the first precursor delivery system 105 but not labeled for clarity with respect to the second precursor delivery system 106 and the third precursor delivery system 108). The carrier gas supply 107 may supply a gas that may be used to help “carry” the precursor gas to the deposition chamber 103. The carrier gas may be an inert gas or other gas that does not react with the precursor material or other materials within the deposition system 100. For example, the carrier gas may be helium (He), argon (Ar), nitrogen (N₂), hydrogen (H₂), combinations of these, or the like, although any other suitable carrier gas may alternatively be utilized.

The carrier gas supply 107 may be a vessel, such as a gas storage tank, that is located either locally to the deposition chamber 103 or else may be located remotely from the deposition chamber 103. Alternatively, the carrier gas supply 107 may be a facility that independently prepares and delivers the carrier gas to the flow controller 109. Any suitable source for the carrier gas may be utilized as the carrier gas supply 107, and all such sources are fully intended to be included within the scope of the embodiments. Additionally, the first precursor delivery system 105, the second precursor delivery system 106, and the third precursor delivery system 108 may share a common carrier gas supply 107.

The carrier gas supply 107 may supply the desired carrier gas to the flow controller 109. The flow controller 109 may be utilized to control the flow of the carrier gas to the precursor canister 111 and, eventually, to the deposition chamber 103, thereby also helping to control the pressure within the deposition chamber 103. The flow controller 109 may be, e.g., a proportional valve, a modulating valve, a needle valve, a pressure regulator, a mass flow controller, combinations of these, or the like. However, any suitable method for controlling and regulating the flow of the carrier gas to the precursor canister 111 may be utilized, and all such components and methods are fully intended to be included within the scope of the embodiments.

The flow controller 109 may supply the controlled carrier gas to the precursor canister 111. The precursor canister 111 may be utilized to supply a desired precursor to the deposition chamber 103 by vaporizing or sublimating precursor materials that may be delivered in either a solid or liquid phase. The precursor canister 111 may have a vapor region into which precursor material is driven into a gaseous phase so that the carrier gas from the flow controller 109 may enter the precursor canister 111 and pick-up or carry the gaseous precursor material out of the precursor canister and towards the deposition chamber 103.

However, as one of ordinary skill in the art will recognize, while the first precursor delivery system 105, the second precursor delivery system 106, and the third precursor delivery system 108 have been described herein as having identical components, this is merely an illustrative example and is not intended to limit the embodiments in any fashion. Any type of suitable precursor delivery system, with any type and number of individual components identical to or different from any of the other precursor delivery systems within the deposition system 100, may alternatively be utilized. All such precursor deposition systems are fully intended to be included within the scope of the embodiments.

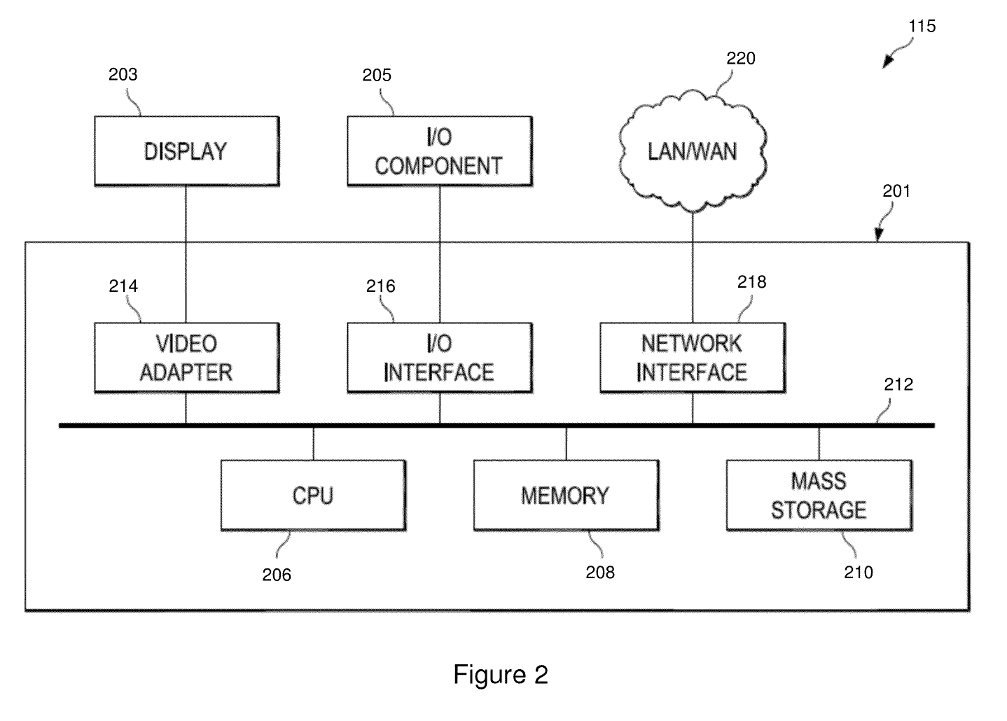

The first precursor delivery system 105, the second precursor delivery system 106, and the third precursor delivery system 108 may supply their individual precursor materials into a precursor gas controller 113 which may connect and isolate the first precursor delivery system 105, the second precursor delivery system 106, and the third precursor delivery system 108 from the deposition chamber 103 in order to deliver the desired precursor material to the deposition chamber 103. The precursor gas controller 113 may include such devices as valves, flow meters, sensors, and the like to control the delivery rates of each of the precursors, and may be controlled by instructions received from the control unit 115 (described further below with respect to FIG. 2).

The precursor gas controller 113, upon receiving instructions from the control unit 115, may open and close valves so as to connect one of the first precursor delivery system 105, the second precursor delivery system 106, and the third precursor delivery system 108 to the deposition chamber 103 and direct a desired precursor material through a manifold 116, into the deposition chamber 103, and to a showerhead 117. The showerhead 117 may be utilized to disperse the chosen precursor material into the deposition chamber 103 and may be designed to evenly disperse the precursor material in order to minimize undesired process conditions that may arise from uneven dispersal. In an embodiment the showerhead 117 may have a circular design with openings dispersed evenly around the showerhead 117 to allow for the dispersal of the desired precursor material into the deposition chamber 103.

However, as one of ordinary skill in the art will recognize, the introduction of precursor materials to the deposition chamber 103 through a single showerhead 117 or through a single point of introduction as described above is intended to be illustrative only and is not intended to be limiting to the embodiments. Any number of separate and independent showerheads 117 or other openings to introduce precursor materials into the deposition chamber 103 may alternatively be utilized. All such combinations of showerheads and other points of introduction are fully intended to be included within the scope of the embodiments.

The deposition chamber 103 may receive the desired precursor materials and expose the precursor materials to the substrate 101, and the deposition chamber 103 may be any desired shape that may be suitable for dispersing the precursor materials and contacting the precursor materials with the substrate 101. In the embodiment illustrated in FIG. 1, the deposition chamber 103 has a cylindrical sidewall and a bottom. However, the deposition chamber 103 is not limited to a cylindrical shape, and any other suitable shape, such as a hollow square tube, an octagonal shape, or the like, may alternatively be utilized. Furthermore, the deposition chamber 103 may be surrounded by a housing 119 made of material that is inert to the various process materials. As such, while the housing 119 may be any suitable material that can withstand the chemistries and pressures involved in the deposition process, in an embodiment the housing 119 may be steel, stainless steel, nickel, aluminum, alloys of these, combinations of these, and like.

Within the deposition chamber 103 the substrate 101 may be placed on a mounting platform 121 in order to position and control the substrate 101 during the deposition process. The mounting platform 121 may include heating mechanisms in order to heat the substrate 101 during the deposition process. Furthermore, while a single mounting platform 121 is illustrated in FIG. 1, any number of mounting platforms 121 may additionally be included within the deposition chamber 103.

Additionally, the deposition chamber 103 and the mounting platform 121 may be part of a cluster tool system (not shown). The cluster tool system may be used in conjunction with an automated handling system in order to position and place the substrate 101 into the deposition chamber 103 prior to the deposition process, position and hold the substrate 101 during the deposition process, and remove the substrate 101 from the deposition chamber 103 after the deposition process.

The deposition chamber 103 may also have an exhaust outlet 125 for exhaust gases to exit the deposition chamber 103. A vacuum pump 123 may be connected to the exhaust outlet 125 of the deposition chamber 103 in order to help evacuate the exhaust gases. The vacuum pump 123, under control of the control unit 115, may also be utilized to reduce and control the pressure within the deposition chamber 103 to a desired pressure and may also be utilized to evacuate precursor materials from the deposition chamber 103 in preparation for the introduction of the next precursor material.

FIG. 2 illustrates an embodiment of the control unit 115 that may be utilized to control the precursor gas controller 113 and the vacuum pump 123 (as illustrated in FIG. 1). The control unit 115 may be any form of computer processor that can be used in an industrial setting for controlling process machines or may alternatively be a general purpose computer platform programmed for such control. In an embodiment the control unit 115 may comprise a processing unit 201, such as a desktop computer, a workstation, a laptop computer, or a dedicated unit customized for a particular application. The control unit 115 may be equipped with a display 203 and one or more input/output components 205, such as instruction outputs, sensor inputs, a mouse, a keyboard, printer, combinations of these, or the like. The processing unit 201 may include a central processing unit (CPU) 206, memory 208, a mass storage device 210, a video adapter 214, and an I/O interface 216 connected to a bus 212.

The bus 212 may be one or more of any type of several bus architectures including a memory bus or memory controller, a peripheral bus, or video bus. The CPU 206 may comprise any type of electronic data processor, and the memory 208 may comprise any type of system memory, such as static random access memory (SRAM), dynamic random access memory (DRAM), or read-only memory (ROM). The mass storage device 210 may comprise any type of storage device configured to store data, programs, and other information and to make the data, programs, and other information accessible via the bus 212. The mass storage device 210 may comprise, for example, one or more of a hard disk drive, a magnetic disk drive, or an optical disk drive.

The video adapter 214 and the I/O interface 216 provide interfaces to couple external input and output devices to the processing unit 201. As illustrated in FIG. 2, examples of input and output devices include the display 203 coupled to the video adapter 214 and the I/O component 205, such as a mouse, keyboard, printer, and the like, coupled to the I/O interface 216. Other devices may be coupled to the processing unit 201, and additional or fewer interface cards may be utilized. For example, a serial interface card (not shown) may be used to provide a serial interface for a printer. The processing unit 201 also may include a network interface 218 that may be a wired link to a local area network (LAN) or a wide area network (WAN) 220 and/or a wireless link.

It should be noted that the control unit 115 may include other components. For example, the control unit 115 may include power supplies, cables, a motherboard, removable storage media, cases, and the like. These other components, although not shown in FIG. 2, are considered part of the control unit 115.

Returning to FIG. 1, the deposition system 100 may be utilized to form a first layer 127 onto the substrate 101. In an embodiment the first layer 127 may be a high-k dielectric layer of a material such as hafnium oxide (HfO₂), zirconium oxide (ZrO₂), lanthanum oxide (La₂O₃), or the like. The first layer 127 may be formed in the deposition chamber 103 utilizing a deposition process such as atomic layer deposition (ALD). However, these materials and processes are intended to be illustrative and are not intended to be limiting, as other desirable materials, such as other dielectric materials, and other suitable deposition processes, such as chemical vapor deposition (CVD) or plasma enhanced CVD (PECVD), may alternatively be utilized.

In an embodiment the formation of the first layer 127 may be initiated by putting a first precursor into the first precursor delivery system 105. For example, in an embodiment in which the first layer 127 is HfO₂, the first precursor material may be a precursor such as hafnium chloride (HfCl₄), hafnium tetrakisdimethylamine, and the hafnium tetrakisdimethylamine may be placed into the first precursor delivery system 105. However, as one of ordinary skill in the art will recognize, these precursors are not the only precursors that may be utilized to form a layer of HfO₂, and the use of hafnium tetrakisdimethylamine is not intended to be limiting to the embodiments. Any suitable precursor material in any suitable phase (solid, liquid, or gas) to form a layer of HfO₂, such as tetrakis ethyl methyl amino hafnium (TEMAH), bis(methylcyclopentadienyl)methoxymethylhafnium (HfD-04), or any other precursor that may be used to form alternative layers, may alternatively be utilized.

Additionally, a second precursor material may be placed into the second precursor delivery system 106. In the embodiment in which a layer of HfO₂ is desired material for the first layer 127, the second precursor material may be a precursor material that may contain oxygen in order to oxidize the first precursor material to form a monolayer of HfO₂. For example, in the embodiment in which hafnium chloride is utilized as the first precursor material, water (H₂O) may be used as the second precursor material and may be placed into the second precursor delivery system 106. However, the description of water as the second precursor material is not intended to be limiting to the embodiments, and any other suitable precursor material, such as oxygen, ozone, N₂O, H₂O—H₂O₂, combinations of these, or the like, may alternatively be utilized as the second precursor material.

Once the first precursor material and the second precursor material have been placed into the first precursor delivery system 105 and the second precursor delivery system 106, respectively, the formation of the first layer 127 may be initiated by the control unit 115 sending an instruction to the precursor gas controller 113 to connect the first precursor delivery system 105 to the deposition chamber 103. Once connected, the first precursor delivery system 105 can deliver the first precursor material (e.g., the hafnium chloride) to the showerhead 117 through the precursor gas controller 113 and the manifold 116. The showerhead 117 can then disperse the first precursor material into the deposition chamber 103, wherein the first precursor material can be adsorbed and react to the exposed surface of the substrate 101.

In the embodiment to form a layer of HfO₂, the first precursor material may be flowed into the deposition chamber 103 at a flow rate of between about 300 sccm and about 400 sccm for about 1 second per cycle. Additionally, the deposition chamber 103 may be held at a pressure of between about 1 torr and about 10 torr, such as about 3 torr, and a temperature of between about 250° C. and about 400° C., such as about 300° C. However, as one of ordinary skill in the art will recognize, these process conditions are only intended to be illustrative, as any suitable process conditions may be utilized while remaining within the scope of the embodiments.

As the first precursor material is adsorbed onto the substrate 101, the first precursor material will react with open active sites located on the exposed surface of the substrate 101. However, once all of the open active sites on the substrate 101 have reacted with the first precursor material, the reaction will stop, as there are no more open active sites to which the first precursor material will bond. This limitation causes the reaction of the first precursor material with the substrate 101 to be self-limiting and to form a monolayer of the reacted first precursor material on the surface of the substrate 101, thereby allowing for a precise control of the thickness of the first layer 127.

However, the substrate 101 is not the only surface within the deposition chamber 103 that adsorbs the first precursor material. Rather, as the first precursor material is dispersed within the deposition chamber 103, the first precursor material is adsorbed on every surface it contacts, including the interior surfaces of the housing 119 that are facing the deposition chamber 103. As such, a monolayer of the first precursor material will also be found on the interior surfaces of the housing 119 of the deposition chamber 103 as well as on the substrate 101.

After the self-limiting reaction on the substrate 101 has finished, the deposition chamber 103 may be purged of the first precursor material. For example, the control unit 115 may instruct the precursor gas controller 113 to disconnect the first precursor delivery system 105 (containing the first precursor material to be purged from the deposition chamber 103) and to connect a purge gas delivery system 114 to deliver a purge gas to the deposition chamber 103. In an embodiment the purge gas delivery system 114 may be a gaseous tank or other facility that provides a purge gas such as nitrogen, argon, xenon, or other non-reactive gas to the deposition chamber 103. Additionally, the control unit 115 may also initiate the vacuum pump 123 in order to apply a pressure differential to the deposition chamber 103 to aid in the removal of the first precursor material. The purge gas, along with the vacuum pump 123, may purge the first precursor material from the deposition chamber 103 for about 3 seconds.

However, while the purge of the first precursor material may remove the first precursor material from the ambient atmosphere within the deposition chamber 103, the purge does not remove the first precursor material from where it had been adsorbed and/or reacted. In particular, the purge of the first precursor material may not remove the first precursor material that has been adsorbed onto the interior surfaces of the housing 119 of the deposition chamber 103. As such, the first precursor material may remain upon the interior surfaces of the housing 119 of the deposition chamber 103 even after the purge.

After the purge of the first precursor material has been completed, the introduction of the second precursor material (e.g., water) to the deposition chamber 103 may be initiated by the control unit 115 sending an instruction to the precursor gas controller 113 to disconnect the purge gas delivery system 114 and to connect the second precursor delivery system 106 (containing the second precursor material) to the deposition chamber 103. Once connected, the second precursor delivery system 106 can deliver the second precursor material to the showerhead 117. The showerhead 117 can then disperse the second precursor material into the deposition chamber 103, wherein the second precursor material can be adsorbed on the surface of the substrate 101 and react with the first precursor material in another self-limiting reaction to form a monolayer of the desired material, e.g., HfO₂, on the surface of the substrate 101.

In the embodiment discussed above to form a layer of HfO₂ with water, the water may be introduced into the deposition chamber 103 at a flow rate of between about 300 sccm and about 400 sccm, such as about 325 sccm, for about 10 seconds. Additionally, the deposition chamber 103 may be held at a pressure of between about 1 torr and about 10 torr and a temperature of between about 250° C. and about 400° C. However, as one of ordinary skill in the art will recognize, these process conditions are only intended to be illustrative, as any suitable process conditions may be utilized to introduce oxygen while remaining within the scope of the embodiments.

However, as the showerhead 117 evenly disperses the second precursor material throughout the deposition chamber 103, the second precursor material does not react solely with the first precursor material that reacted with the surface of the substrate 101. Rather, the second precursor material reacts with the first precursor material wherever it is located within the deposition chamber 103. As such, the second precursor material also reacts with the first precursor material that had been adsorbed onto the interior surfaces of the housing 119 of the deposition chamber 103 and forms a second layer 129 along the interior surfaces of the housing 119 of the deposition chamber 103 as well as on the surface of the substrate 101.

After the monolayer of the desired material, e.g., HfO₂, has been formed, the deposition chamber 103 may be purged (leaving behind the monolayer of the desired material on the substrate 101 and the interior surfaces of the deposition chamber 103) using, e.g., a purge gas from the purge gas delivery system 114 for about three seconds. After the deposition chamber 103 has been purged, a first cycle for the formation of the desired material has been completed, and a second cycle similar to the first cycle may be started. For example, the repeated cycle may introduce the first precursor material for about 1 second, purge with the purge gas for about 3 seconds, pulse with the second precursor for about 10 seconds, and purge with the purge gas for about 3 seconds. These cycles may be repeated until the first layer 127 on the substrate 101 has a thickness of between about 10 Å and about 20 Å, such as between about 15 cycles and about 25 cycles, such as about 20 cycles. Once the desired thickness of the first layer 127 has been reached, the substrate 101 may be removed from the deposition chamber 103 for further processing.

However, as one of ordinary skill in the art will recognize, the above described process to form the first layer 127 is intended to be illustrative and is not intended to be limiting to the embodiments. Any other suitable process, such as initially pulsing the second precursor material (e.g., water) for about 10 seconds, purging with the purge gas for about 3 seconds, introducing the first precursor material (e.g., hafnium chloride) for about 1 second, and purging with the purge gas for 3 seconds to complete a first cycle and then repeating the first cycle, may alternatively be utilized. This and any other suitable process to form the first layer 127 are fully intended to be included within the scope of the embodiments.

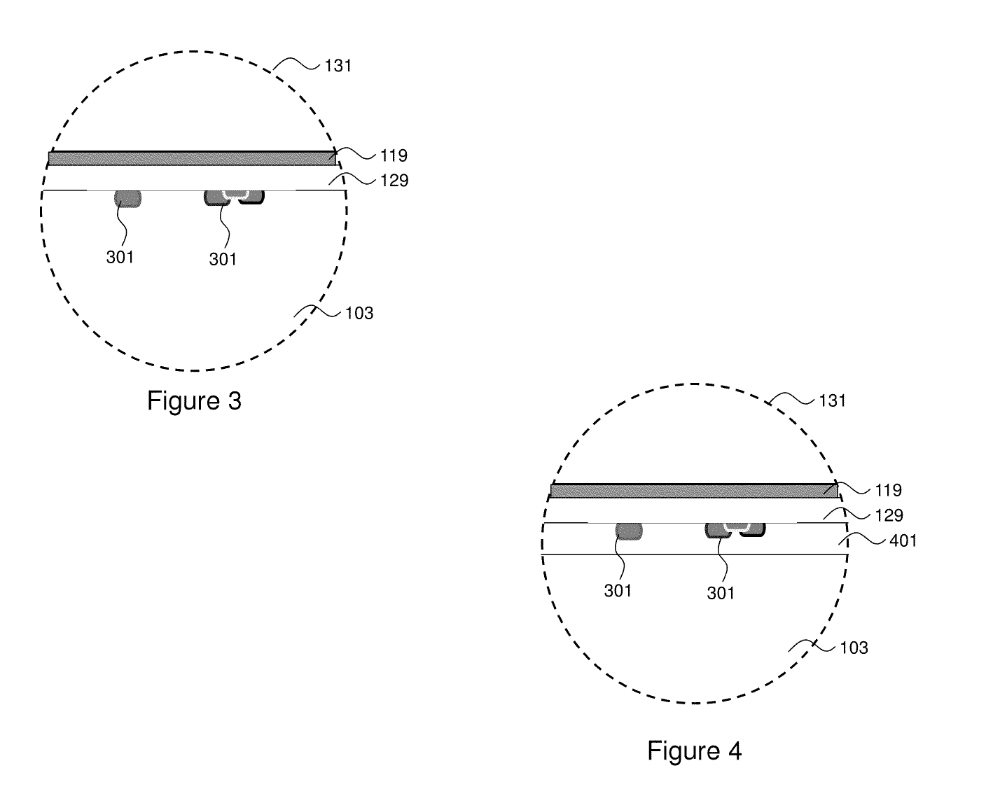

FIG. 3 illustrates a close up view of the housing 119 of the deposition chamber 103 within the dashed circle 131 (see FIG. 1) after the second layer 129 has been formed simultaneously with the first layer 127 (not shown in FIG. 3 but illustrated in FIG. 1). As illustrated, the second layer 129 will form along the interior surfaces of the housing 119 facing the deposition chamber 103, with the second layer 129 growing in thickness with each repetition of the deposition process similar to the first layer 127. However, because the second layer 129 may be formed of a ceramic material with a low ductility and may have a weak adherence to the housing 119 of the deposition chamber 103, the second layer 129 may crystallize and fracture to form particles 301 or projections that can grow with each deposition cycle. Once enough deposition cycles have occurred (from processing multiple substrate 101 within the deposition chamber), these particles 301 may reach a certain size, such as over about 1 μm, and the particles 301 may undesirably break off of the second layer 129 and land on a substrate 101 being processed, causing defects in the substrate 101 that is being processed at the time.

FIG. 4 illustrates a solution to this problem of the second layer 129 crystallizing and fracturing on the interior surfaces of the housing 119 of the deposition chamber 103. In an embodiment, after the second layer 129 has been formed on the interior surfaces of the housing 119 of the deposition chamber 103 (through one or more cycles of the deposition process), the deposition chamber 103 may be conditioned in order to lower the surface energy of the second layer 129 and encapsulate the particles 301 of the second layer 129 and prevent the particles 301 from coming off during a subsequent deposition process. This conditioning may be done prior to the particles 301 becoming large enough to cause problems, such as when the particles are less than about 1 μm, which may occur before the deposition chamber 103 has performed between about 3,000 cycles and about 3,500 cycles, such as about 3,250 cycles.

To condition the deposition chamber 103, a third layer 401 may be formed over the second layer 129 and over the particles 301, effectively encapsulating the particles 301 within the second layer 129. In an embodiment, the third layer 401 may be formed by initiating a second deposition process in the deposition chamber 103 without a substrate 101 being located within the deposition chamber 103. As such, the deposition will occur on the interior surfaces of the housing 119 of the deposition chamber 103 and not on a substrate 101. By forming the third layer 401 over the second layer 129, the third layer 401 will form over and prevent the particles 301 from breaking off the second layer 129.

Additionally, in order to avoid forming just another monolayer of the second layer 129 (e.g., another monolayer of HfO₂), the third layer 401 may be formed using a third precursor material that can compete against the first precursor material to react with a hydroxyl (OH) of the second layer 129 (supplied by the second precursor material) to form a heterogeneous thin film different from the second layer 129. For example, in an embodiment in which the second layer 129 is HfO₂, the third layer 401 may be a different material than the second layer 129, such as aluminum oxide (Al₂O₃). However, as one of ordinary skill in the art will recognize, Al₂O₃ is presented as an illustrative material only, as any other suitable material that is not the same as the second layer 129, such as zirconium oxide (ZrO₂), lanthanum oxide (La₂O₃), tantalum oxide (Ta₂O₅), yttrium oxide (Y₂O₃), combinations of these, or the like, may alternatively be utilized. All such materials are fully intended to be included within the scope of the embodiments.

The third layer 401 may be formed using a similar ALD process as the second layer 129 or may be formed using a different deposition process such as CVD. In an embodiment utilizing ALD, the conditioning deposition process for the third layer 401 may be initiated by placing a third precursor material for the third layer 401 in the third precursor delivery system 108. In an embodiment in which Al₂O₃ is utilized as the third layer 401, the third precursor material may again be a precursor that chemically competes to react with the hydroxyl (OH) of the second layer 129, such as trimethyl aluminum (TMA). However, any other suitable precursor materials, such as aluminum trichloride, triethylaluminum, chlorodemethylaluminum, aluminum ethoxide, aluminum isopropoxide, and the like, in any suitable phase (solid, liquid, or gas), may alternatively be utilized.

Once the third precursor material has been placed into the third precursor delivery system 108, the deposition process may be initiated by the control unit 115 sending instructions to the precursor gas controller 113 to connect the third precursor delivery system 108 to the showerhead 117, which will disperse the third precursor material into the deposition chamber 103. Once dispersed within the deposition chamber 103, the third precursor material may adsorb onto the second layer 129 (including the particles 301) and react to form a monolayer of the third precursor material over the second layer 129 and the particles 301.

In an embodiment, the third precursor material may be introduced to the deposition chamber 103 at a flow rate of about 800 sccm for a time of between about 0.3 seconds and about 0.7 seconds, such as about 0.5 seconds per cycle. During the deposition process, the deposition chamber 103 may be held at a pressure of between about 5 torr and about 10 torr, such as about 7 ton, and a temperature of between about 250° C. and about 400° C., such as about 300° C.

After the third precursor material has been adsorbed on the surface of the second layer 129 and completed the self-limiting reaction to form the monolayer of the third precursor material onto the second layer 129 and the particles 301, the deposition chamber 103 may be purged of the third precursor material. For example, the control unit 115 may instruct the precursor gas controller 113 to disconnect the third precursor delivery system 108 (containing the third precursor material) and to connect the purge gas delivery system 114 to deliver a purge gas such as argon, xenon, or other non-reactive gas to the deposition chamber 103. The purge gas, along with the vacuum pump 123, may be used to purge the third precursor material from the deposition chamber 103 for a time of about 3 seconds.

After the purge has been completed, the introduction of a fourth precursor material to the deposition chamber 103 may be initiated by the control unit 115 by sending an instruction to the precursor gas controller 113 to disconnect the purge gas delivery system 114 and to connect the deposition chamber 103 to the fourth precursor material, which may be used to, e.g., oxidize the fourth precursor material. If the fourth precursor material is the same as the second precursor material (e.g., water), the control unit 115 may connect the second precursor delivery system 106 (containing water) to the deposition chamber 103. However, in an embodiment in which the fourth precursor material is not the same as the second precursor material, such as being oxygen, ozone, N₂O, H₂O—H₂O₂, or the like, the control unit 115 may instruct the precursor gas controller 113 to connect a fourth precursor delivery system (not shown in FIG. 1) to the deposition chamber 103 to introduce the fourth precursor material.

In an embodiment the fourth precursor material may be introduced to the deposition chamber at a flow rate of between about 300 sccm and about 400 sccm for a time of about 0.5 seconds per cycle. Additionally, the deposition chamber 103 may be held at a pressure of between about 1 torr and about 10 torr, such as about 3 torr, and a temperature of between about 250° C. and about 400° C., such as about 300° C.

Once the fourth precursor material has been dispersed into the deposition chamber 103, the fourth precursor material may be adsorbed on the second layer 129, where it will react with the third precursor material to form the third layer 401 as a monolayer of the desired material, e.g., Al₂O₃, on the second layer 129. By forming the third layer 401 over the second layer 129 and the particles 301 generated from the third layer 401, the surface energy of the particles 301 are reduced and the particles 301 are encapsulated by the third layer 401, thereby preventing them from dislodging during subsequent process runs and increasing the usable life span of the deposition chamber 103 before preventative maintenance needs to be performed.

After the third layer 401 has been formed as a monolayer, the deposition chamber 103 and manifold 116 may again be purged using a purge gas for about 3 seconds, and the cycle may be repeated to form another monolayer of the third layer 401 onto the substrate 101 and to make the third layer 401 thicker. This cycle may be repeated as often as desired to form any desired thickness of the third layer 401. In an embodiment the conditioning process may comprise 500 cycles and may form the third layer 401 to a thickness of between about 500 Å and about 800 Å, such as about 500 Å.

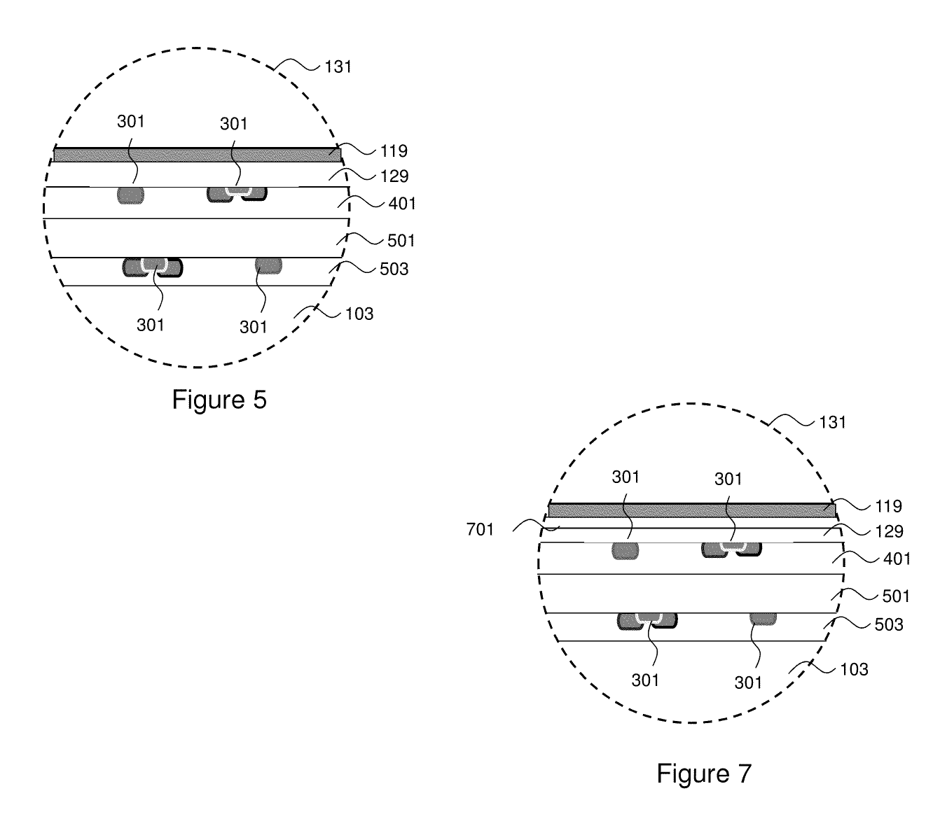

FIG. 5 illustrates further deposition processes that may occur within the deposition chamber 103 followed by further conditioning of the deposition chamber 103. As illustrated, after the third layer 401 has conditioned the second layer 129, the deposition chamber 103 may again be used to deposit layers onto another substrate 101. However, similar to the co-deposition of the first layer 127 and the second layer 129, with each additional deposition process another layer, such as the fourth layer 501 illustrated in FIG. 5, may be formed over the third layer 401 along the surface of the housing 119 of the deposition chamber 103, along with additional particles 301 that may be formed from the crystallization and fracturing of the fourth layer 501.

As such, the deposition chamber 103 may again be conditioned in order to encapsulate the particles 301 from the fourth layer 501. In an embodiment the conditioning may be performed similar to the conditioning described above with respect to FIG. 4. For example, a fifth layer 503 may be deposited over the fourth layer 501, and the fifth layer 503 may comprise a material that is heterogeneous to the fourth layer 501 in order to encapsulate the particles 301 from the fourth layer 501.

This cycle of alternating deposition and conditioning may be under the control of the control unit 115, which may initiate the conditioning procedure periodically and automatically. In an embodiment, the control unit 115 may initiate the conditioning procedure as needed to keep the particles 301 from breaking off and redepositing on a wafer, such as about every 3,250 deposition cycles. For example, the control unit 115 may initiate 3,250 deposition cycles, automatically initiate a conditioning process (with 500 conditioning cycles) after the 3,250 deposition cycles, and follow that with a purge of the deposition chamber 103 and the manifold 116.

Alternatively, the control unit 115 may initiate the conditioning cycle based on the number of wafers that have been processed within the deposition chamber 103. In an embodiment, the control unit 115 may periodically condition the deposition chamber 103 to form a condition layer (e.g., the third layer 401 or the fifth layer 503) that may be 500 Å thick after processing 250 wafers. Such conditioning is shown in a first region 601 of the chart in FIG. 6, where the y-axis represents the mean count of particles 301 greater than 1 μm, and wherein the first region has a mean count of particles of about 6.1. In another embodiment, the control unit 115 may periodically condition the deposition chamber 103 with a conditioning layer that may be 800 Å thick after processing 250 wafers. Such conditioning is shown in a second region 603 of the chart in FIG. 6 and results in a mean particle count of about 3.7. In yet another embodiment, the control unit 115 may periodically condition the deposition chamber 103 with a conditioning layer that is 500 Å thick after processing between about 141 wafers and about 175 wafers, such as about 163 wafers. Such conditioning is shown in a third region 605 of the chart in FIG. 6 and results in a mean particle count of about 1.5. As illustrated, the conditioning of the deposition chamber 103 may reduce the mean count of particles greater than 1 μm, which can increase the overall life span of the deposition chamber 103 before a full preventative maintenance process is performed.

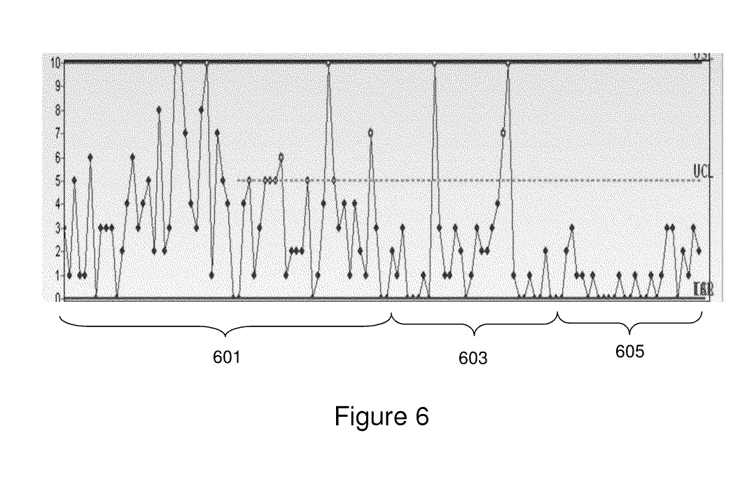

FIG. 7 illustrates another embodiment in which the interior surface of the housing 119 of the deposition chamber 103 may be preconditioned prior to the formation of the second layer 129 by forming a sixth layer 701 prior to the first deposition process that forms the second layer 129. In this embodiment the sixth layer 701 may be formed from similar materials and using similar processes as the third layer 401, such as Al₂O₃ formed by ALD, although any suitable material and process may alternatively be utilized. By preconditioning the housing 119 of the deposition chamber 103, the sixth layer 601 may help the second layer 129 adhere to the housing 119 and help to further reduce the crystallizing and fracturing of the second layer 129 that forms the particles 301.

By conditioning the deposition chamber 103 as described in the embodiments above, the life span of the deposition chamber 103 may be prolonged before preventative maintenance is performed. By extending the time periods between preventative maintenance, less time and money are needed to ensure that the deposition chamber 103 is functioning adequately, and more deposition cycles may be performed for a lower cost and in a shorter amount of time. This can make the overall manufacturing costs lower and make the overall manufacturing process more efficient than if the conditioning is not performed.

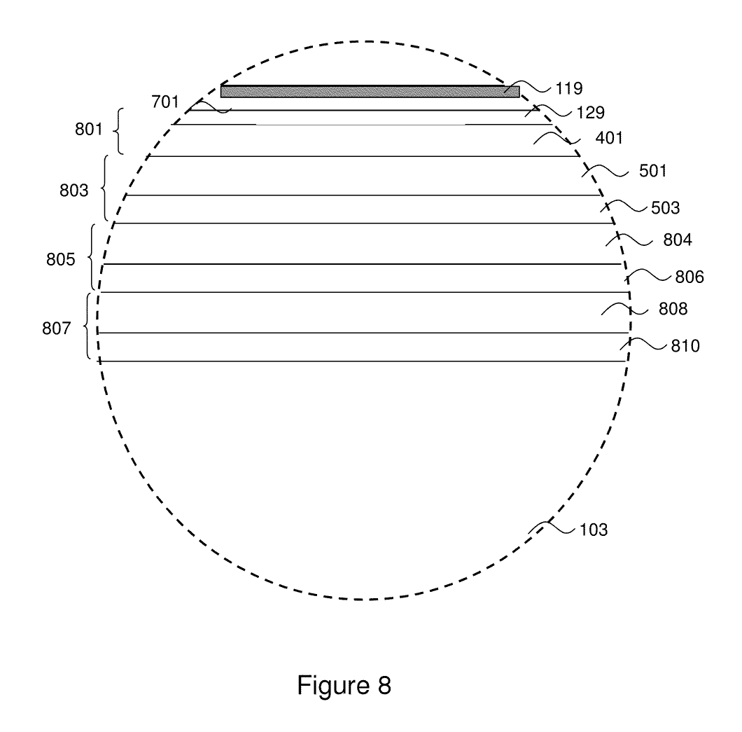

FIG. 8 illustrates a continuation of the conditioning process on the housing 119 of the deposition chamber 103. In this embodiment a combination of a processing layer, such as the second layer 129 (e.g., HfO₂, formed during the processing of wafers) and a conditioning layer, such as the third layer 401 (e.g., Al₂O₃) may comprise a first bi-layer 801. This process may be repeated to form a second bi-layer 803 of conditioned material (which may include the fourth layer 501 of, e.g., HfO₂, and the fifth layer 503 of e.g., Al₂O₃), a third bi-layer 805 (which may contain a sixth layer 804 of, e.g., HfO₂, and a seventh layer 806 of, e.g., Al₂O₃), and a fourth bi-layer 807 (which may contain an eight layer 808 of, e.g., HfO₂, and a ninth layer 810 of, e.g., Al₂O₃).

Any suitable number of bi-layers such as the first bi-layer 801 and the second bi-layer 803 may be formed to condition the housing 119 before maintenance is performed on the housing 119. For example, if the specification of the particle count tolerance is 5 e.a., thirty bi-layers may be formed on the housing 119 before maintenance is performed. Alternatively, if the specification of the particle count tolerance is 10 e.a. with the particle size over 1 mm, seventy bi-layers may be formed on the housing 119 prior to maintenance being performed. However, any suitable number of bi-layers may be formed in order to condition the housing 119 of the deposition chamber 103.

In accordance with an embodiment, a method for depositing materials comprising forming a first layer on a surface of a deposition chamber, the first layer comprising a first material and having projections, is provided. The deposition chamber is conditioned after the forming the first material, the conditioning forming a second layer over the first material and the projections, the second layer comprising a second material different from the first material.

In accordance with another embodiment, a method of depositing materials comprising depositing a first material onto a first substrate in a deposition chamber, the depositing the first material also forming a first layer of the first material on a surface of the deposition chamber, is provided. The first substrate is removed from the deposition chamber, and a second material is deposited over the first layer, wherein the first material and the second material are heterogeneous to each other.

In accordance with yet another embodiment, a method of depositing materials comprising depositing a first high-k dielectric material onto a first substrate and onto a surface of a chamber, the depositing the first high-k dielectric material being performed at least in part using an atomic layer deposition process, is provided. The first substrate is removed from the chamber, and the first high-k dielectric material on the surface of the chamber is encapsulated by depositing a second dielectric material over the first high-k dielectric material, the second dielectric material being different from the first high-k dielectric material.

Although the embodiments and their advantages have been described in detail, it should be understood that various changes, substitutions and alterations can be made herein without departing from the spirit and scope of the embodiments. For example, the precise precursor materials chosen to form the conditioning layer may be modified while remaining within the scope of the embodiments. As another example, it will be readily understood by those skilled in the art that process conditions and materials may be varied while also remaining within the scope of the embodiments.

Moreover, the scope of the present application is not intended to be limited to the particular embodiments of the process, machine, manufacture, composition of matter, means, methods and steps described in the specification. As one of ordinary skill in the art will readily appreciate from the disclosure of the embodiments, processes, machines, manufacture, compositions of matter, means, methods, or steps, presently existing or later to be developed, that perform substantially the same function or achieve substantially the same result as the corresponding embodiments described herein may be utilized according to the embodiments. Accordingly, the appended claims are intended to include within their scope such processes, machines, manufacture, compositions of matter, means, methods, or steps.

What is claimed is:

1. A method for depositing materials, the method comprising:
forming a first layer on a surface of a deposition chamber, the first layer comprising a first material and having projections; and
conditioning the deposition chamber after the forming the first material, the conditioning forming a second layer over the first material and the projections, the second layer comprising a second material different from the first material.

2. The method of claim 1, further comprising preconditioning the deposition chamber prior to the forming the first material, the preconditioning the deposition chamber further comprising forming a third layer directly on the surface of the deposition chamber prior to the forming the first layer.

3. The method of claim 1, wherein the second material comprises aluminum oxide.

4. The method of claim 1, further comprising forming a third layer over the second layer, the third layer comprising the first material.

5. The method of claim 1, wherein the first layer comprises hafnium oxide and wherein the conditioning the deposition chamber forms a layer of aluminum oxide.

6. The method of claim 1, further comprising:
forming a third layer on the second layer, the third layer comprising a third materil; and
conditioning the deposition chamber after the forming the third layer, the conditioning the deposition chamber after the forming the third layer forming a fourth layer over the third material, the fourth layer comprising a fourth material different from the third material.

7. The method of claim 1, wherein the second layer has a thickness of about 500 Å and the conditioning is performed after the forming the first layer has been repeated 250 times.

8. A method of depositing materials, the method comprising:
depositing a first material onto a first substrate in a deposition chamber, the depositing the first material also forming a first layer of the first material on a surface of the deposition chamber;
removing the first substrate from the deposition chamber; and
depositing a second material over the first layer, wherein the first material and the second material are heterogeneous to each other.

9. The method of claim 8, further comprising:
depositing a third material over the second material; and
depositing a fourth material over the third material, wherein the third material and the fourth material are heterogeneous to each other.

10. The method of claim 8, further comprising placing a second substrate in the deposition chamber after the removing the first substrate and prior to the depositing the second material.

11. The method of claim 8, wherein the first material is a high-k-dielectric layer.

12. The method of claim 11, wherein the first material is hafnium oxide.

13. The method of claim 12, wherein the second material is aluminum oxide.

14. The method of claim 8, wherein the depositing the first material is performed at least in part through an atomic layer deposition.

15. The method of claim 8, wherein the second material has a thickness of about 500 Å and the depositing the second material is performed after the depositing a first material has been repeated 250 times

16. A method of depositing materials, the method comprising:
depositing a first high-k dielectric material onto a first substrate and onto a surface of a chamber, the depositing the first high-k dielectric material being performed at least in part using an atomic layer deposition process;
removing the first substrate from the chamber; and
encapsulating the first high-k dielectric material on the surface of the chamber by depositing a second dielectric material over the first high-k dielectric material, the second dielectric material being different from the first high-k dielectric material.

17. The method of claim 16, further comprising placing a second substrate into the chamber after the removing the first substrate and prior to the encapsulating the first high-k dielectric material.

18. The method of claim 16, wherein the encapsulating the first high-k dielectric material is performed while there is no substrate within the chamber.

19. The method of claim 16, wherein the depositing the second dielectric material deposits a layer of aluminum oxide.

20. The method of claim 16, wherein the encapsulating the first high-k dielectric material occurs automatically after the depositing the first layer.
